(19) United States
(12) Patent Application Publication
(10) Pub. No.: US 2009/0108276 A1
(43) Pub. Date: Apr. 30, 2009

(54) High Efficiency Dilute Nitride Light Emitting Diodes

(76) Inventors: Charles Tu, La Jolla, CA (US); Vladimir Odnoblyudov, La Jolla, CA (US)

Correspondence Address: MINTZ, LEVIN, COHN, FERRIS, GLOVSKY AND POPEO, P.C, ONE FINANCIAL CENTER, BOSTON, MA, 02111, US

(21) Appl. No.: 12/263,288

(22) Filed: Oct. 31, 2008

Related U.S. Application Data
(63) Continuation of application No. 11/576,992, filed on Apr. 10, 2007.
(60) Provisional application No. 60/617,465, filed on Oct. 8, 2004.

(51) Int. Cl. H01L 33/00; H01L 21/02

(52) U.S. Cl. 257/94; 257/99; 438/46; 257/E33.023; 257/E21.04

(57) ABSTRACT

A light-emitting diode comprising AlₙInₘGa₁₋ₘ₋ₙN_{c}AsᵥSbₖP_{1-c-v-k} where 0.001<c<0.1 and 0≦n, m, v, k≦1 adapted to emit light in a wavelength range of about 540 nm to about 700 nm.

### CROSS-REFERENCES TO RELATED APPLICATIONS

This patent application is a continuation-in-part of U.S. patent application Ser. No. 11/576,992, entitled “HIGH EFFICIENCY LIGHT-EMITTING DIODES,” filed Apr. 10, 2007, which is a U.S. national phase application of International Application No. PCT/US2005/036538, entitled “HIGH EFFICIENCY LIGHT-EMITTING DIODES,” filed Oct. 8, 2005, which is a patent application under the Paris Convention Treaty of U.S. Provisional Patent Application No. 60/617,465, entitled “HIGH EFFICIENCY LED'S AND LASERS,” filed Oct. 8, 2004. The disclosures of these three applications are hereby incorporated by reference in their entirety for all purposes.

### BACKGROUND OF THE INVENTION

This application relates to high efficiency light-emitting diodes directly grown over transparent GaP substrates.

Solid-state lighting with light emitting diodes (LEDs) has become one of the most exciting subjects in research and business. Applications for these LEDs include full-color displays, signaling, traffic lights, automotive lights, and back lighting of cell phones, among others. LEDs emitting white light are desired to replace incandescent and fluorescent lamps for general lightning.

There are three main approaches to the production of white light: (1) using blue light-emitting devices with yellow phosphors; (2) using ultraviolet light-emitting devices with white phosphors; and (3) using tricolor mixing from a set of fundamental colors. This last technique is often referred to as the “RGB approach,” making reference to the use of red, green, and blue light-emitting devices to provide the set of fundamental colors. Effective tricolor mixing is achieved with light-emitting devices that provide light at approximately 460 nm, 540 nm, and 610 nm. The two shorter wavelengths (460 and 540 nm) can be produced using AlGaInN light-emitting devices and the longer wavelength (610 nm) can be produced from AlGaInP light-emitting devices grown on GaAs substrates. While this red, green and blue (RGB) method is quite common, other combinations of different color LEDs may be used. The approach using LEDs and no phosphors provides a wider color range than combining LEDs and phosphors. In other applications the multiple LED approach may be used to generate any color light by suitable adjustment of the individual current in the different color LEDs.

There are a number of known difficulties with currently used yellow-red AlInGaP-based light emitting devices. For example, they suffer from low internal quantum efficiency and poor temperature stability in the yellow-red range, which is usually attributed to poor electron confinement. In addition, the conventional procedure for removing the light absorbing GaAs substrate and wafer bonding a transparent substrate or reflective layer to the formed layer has a low yield and adds several relatively expensive processing steps, thus resulting in high costs.

There is accordingly a general need in the art for improved methods and systems for forming light emitting devices.

### BRIEF SUMMARY OF THE INVENTION

In the following description and claims, the terms “comprise” and “include,” along with their derivatives, may be used and are intended as synonyms for each other and mean that addition of unnamed extra elements is not precluded. In addition, in the following description and claims, the terms “coupled” and “connected,” along with their derivatives, may be used.

As used herein, the term “connected” may be used to indicate that two or more elements are in direct physical or electrical contact with each other. The term “coupled” may mean that two or more elements are in direct physical or electrical contact. However, “coupled” may also mean that two or more elements are not in direct contact with each other, but yet still co-operate or interact with each other. For example, “coupled” may mean that two or more elements do not contact each other but are indirectly joined together via another element or intermediate elements.

As used herein, the terms “on,” “overlying,” and “over” may be used in the following description and claims. “On,” “overlying,” and “over” may be used to indicate that two or more elements are in direct physical contact with each other. However, “over” may also mean that two or more elements are not in direct contact with each other. For example, “over” may mean that one element is above another element but not contact each other and may have another element or elements in between the two elements. It should be noted that “overlying” and “over” are relative terms that include layers located beneath a substrate when the substrate is turned upside down.

As used herein, the term “group III” elements indicates the elements found in what is commonly referred to as group III of the periodic table. For example, boron (B), aluminum (Al), gallium (Ga), and indium (In) are group III elements. Similarly, the term “group V” elements indicates the elements found in what is commonly referred to as group V of the periodic table. For example, nitrogen (N), phosphorus (P), arsenic (As), antimony (Sb), and bismuth (Bi) are group V elements.

Embodiments of the invention provide a LED comprising a direct-bandgap active layer comprising a dilute nitride semiconductor AlₙInₘGa₁₋ₙ₋ₘN_{c}AsᵥSbₖP_{1-c-v-k}, where 0≦n, m, v, k≦1 and a non-zero c, such as c>0.004, for example 0.001<c<0.1, formed over a substrate to generate light in the ROY wavelength range. The active layer may also comprise a plurality of layers in some embodiments. In some embodiments the substrate may be either GaP or silicon, however this is not a limitation of the present invention and in other embodiments other substrates may be used.

In some embodiments, the AlₙInₘGa₁₋ₘ₋ₙN_{c}AsᵥSbₖP_{1-c-v-k} layer where 0.001<c<0.1 and 0≦n,m,v,k≦1 may comprise InₘGa₁₋ₘN_{c}P_{1-c} where 0.001<c<0.1 and 0≦m≦1, preferably 0.001<c<0.03 (such as c>0.004) and 0.02≦m≦0.20. In some embodiments the AlₙInₘGa₁₋ₘ₋ₙN_{c}AsᵥSbₖP_{1-c-v-k} layer where 0.001<c<0.1 and 0≦n,m,v,k≦1 may comprise GaN_{c}AsᵥP_{1-c-v} layer where 0.001<c<0.1 and 0≦v≦1, preferably 0.001<c<0.04 and 0.05≦v≦0.3. In some embodiments the AlₙInₘGa₁₋ₘ₋ₙN_{c}AsᵥSbₖP_{1-c-v-k} layer where 0.001<c<0.1 and 0≦n,m,v,k≦1 may comprise GaN_{c}P_{1-c} layer where 0.001<c<0.1, preferably 0.001<c<0.03. In some embodiments the AlₙInₘGa₁₋ₘ₋ₙN_{c}AsᵥSbₖP_{1-c-v-k} layer where 0.001<c<0.1 and 0≦n,m,v,k≦1 may comprise GaN_{c}AsᵥSbₖP_{1-c-v-k} layer where 0.001<c<0.1 and 0≦v,k≦1, preferably 0.001<c<0.03, 0.05≦v≦0.3, and 0.001≦k≦0.3. In some embodiments the AlₙInₘGa₁₋ₘ₋ₙN_{c}AsᵥSbₖP_{1-c-v-k} layer where 0.001<c<0.1 and 0≦n,m,v,k≦1 may comprise InₘGa₁₋ₘN_{c}AsᵥP_{1-c-v} layer where 0.001<c<0.1 and 0≦m, v≦1. In some embodiments the AlₙInₘGa₁₋ₘ₋ₙN_{c}AsᵥSbₖP_{1-c-v-k} layer where 0.001<c<0.1 and 0≦n,m,v,k≦1 may comprise InₘGa₁₋ₘN_{c}AsᵥSbₖP_{1-c-v-k} layer where 0.001<c<0.1 and 0≦m,v,k≦1. However these examples are not meant to be limitations of the present invention and in other embodiments the layer may AlₙInₘGa₁₋ₘ₋ₙN_{c}AsᵥSbₖP_{1-c-v-k} layer where 0.001<c<0.1 and 0≦n,m,v,k≦1, that is n, m, v and k may individually have any value between and including zero and one.

One set of embodiments of the invention includes an LED structure comprising one or a plurality of active layers that comprise at least one element selected from the group consisting of Al, In, and Ga; N in a concentration range from about 0.001≦[N]≦0.1, preferably in the range from about 0.004≦[N]≦0.02; and at least one element selected from the group consisting of As, Sb, and P. The one or more active layers may be interleaved with a plurality of barrier layers comprising AlₙGa₁₋ₙP where 0≦n≦1. The bandgap of the barrier layers may be larger than that of the active layer. The larger bandgap of the barrier layers may aid in confinement of electrical carriers (holes and electrons) in the active layer.

The plurality of active layers interleaved with the plurality of barrier layers as a whole are referred to as an active region that emits light. In a specific embodiment of the invention, the one or more active layers may have a higher luminescence efficiency and a smaller shift in emitted wavelength, as well as better temperature stability, than a LED formed from the conventional AlInGaP material system.

In some embodiments, an optional AlₓGa₁₋ₓP where 0≦x≦1 buffer layer may be formed over the substrate prior to formation of the lower buffer layer. In some embodiments, an optional Al_{w}Ga_{1-w}P where 0≦w≦1 hole-leakage prevention layer may be formed over the substrate or buffer layer prior to the formation of the active region. The bandgap of the hole-leakage prevention layer may be greater than that of the buffer layer. For example the buffer layer may comprise AlₓGa₁₋ₓP and the hole-leakage prevention layer may comprise Al_{w}Ga_{1-w}P with w>x. In another example the buffer layer may comprise GaP and the hole-leakage prevention layer may comprise AlₓGa₁₋ₓP where 0<x≦1.

In some embodiments of the invention, an AlₙInₘGa₁₋ₘ₋ₙP where 0≦n,m≦1 cap/contact layer may be formed over the previously formed layers as a final layer. The bandgap of the cap/contact layer may be greater than (as shown in FIG. 2), the same as, or less than (as shown in FIG. 4) that of the layer over which it is formed.

In some embodiments of the invention, an optional Al_{y}Ga_{1-y}P where 0≦y≦1 current spreading/blocking layer may be formed over, within or under the cap/contact layer. The bandgap of the current spreading/blocking layer may be greater than that of the cap/contact layer.

In some embodiments of the invention, an optional Al_{y}Ga_{1-y}P where 0≦y≦1 current spreading/blocking layer may be formed over, within or under the buffer layer. The bandgap of the current spreading/blocking layer may be greater than that of the buffer layer.

In some embodiments the AlₙInₘGa₁₋ₘ₋ₙN_{c}AsᵥSbₖP_{1-c-v-k} layer where 0.001<c<0.1 and 0≦n,m,v,k≦1 may be annealed, such as by thermally annealing at an annealing temperature that exceeds the deposition temperature. In some embodiments, the annealing may take place in the same processing chamber in which the layer formation occurs. In other embodiments, the annealing may take place in a different processing chamber or tool.

In another specific embodiment of the invention, the LED structure may comprise a GaP substrate over which is formed a GaP buffer layer, over which is formed an active region comprising interleaved layers of a GaP barrier layer and an AlₙInₘGa₁₋ₘ₋ₙN_{c}AsᵥSbₖP_{1-c-v-k} layer where 0.001<c<0.1 and 0≦n,m,v,k≦1 active layer, over which is formed a GaP cap/contact layer. In some embodiments of this specific structure, the GaP substrate and GaP buffer layer may be n-type and the cap/contact layer may be p-type. In other embodiments, the GaP substrate and GaP buffer layer may be p-type and the cap/contact layer may be n-type.

In another specific embodiment of the invention, the LED structure may comprise a GaP substrate over which is formed a GaP buffer layer, over which is formed an active region comprising interleaved layers of a GaP barrier layer and a InₘGa₁₋ₘN_{c}P_{1-c} layer where 0.001<c<0.05 and 0≦m≦0.4 active layer, over which is formed a GaP cap/contact layer. In some embodiments of this specific structure, the GaP substrate and GaP buffer layer may be n-type and the cap/contact layer may be p-type. In other embodiments, the GaP substrate and GaP buffer layer may be p-type and the cap/contact layer may be n-type.

In another specific embodiment of the invention, the LED structure may comprise a GaP substrate over which is formed a GaP buffer layer, over which is formed an active region comprising interleaved layers of a GaP barrier layer and a GaN_{c}AsᵥP_{1-c-v} layer where 0.001<c<0.05 and 0≦v≦0.5 active layer, over which is formed a GaP cap/contact layer. In some embodiments of this specific structure, the GaP substrate and GaP buffer layer may be n-type and the cap/contact layer may be p-type. In other embodiments, the GaP substrate and GaP buffer layer may be p-type and the cap/contact layer may be n-type.

### BRIEF DESCRIPTION OF THE DRAWINGS

FIG. 1 is an exemplary depiction of an AlₙInₘGa₁₋ₘ₋ₙN_{c}AsᵥSbₖP_{1-c-v-k} where 0.001<c<0.1 and 0≦n,m,v,k≦1-based LED structure.

FIG. 2 is a schematic of a band diagram of the LED structure of FIG. 1.

FIG. 3A depicts the conduction band offset of an InGaNP/GaP-based LED.

FIG. 3B depicts the conduction band offset of an AlInGaP/AlGaP-based LED.

FIG. 4A is a schematic band diagram of a current spreading/blocking layer between two cap/contact layers or two buffer layers.

FIG. 4B is an illustration of a current spreading through the structure in the absence of a current spreading/blocking layer.

FIG. 4C is an illustration of a current spreading through the structure when a current spreading/blocking layer is included.

FIG. 5 shows the effect of annealing on photoluminescence properties of the InGaNP-based LED on a GaP substrate.

FIG. 6A shows electroluminescence spectra of a fabricated LED of an embodiment of the present invention at various drive currents.

FIG. 6B shows dependence of the red shift in emission peak wavelength upon drive current for a GaNP-based LED of an embodiment of the present invention (curve 702) and for a conventional AlInGaP-based LED (curve 704).

FIG. 7 shows the current-voltage characteristics of a fabricated LED of the present invention.

For simplicity of illustration and ease of understanding, elements in the various figures are not necessarily drawn to scale, unless explicitly so stated. Further, if considered appropriate, reference numerals have been repeated among the figures to indicate corresponding and/or analogous elements. In some instances, well-known methods, procedures, components and circuits have not been described in detail so as not to obscure the present disclosure. The following detailed description is merely exemplary in nature and is not intended to limit the disclosure of this document and uses of the disclosed embodiments. Furthermore, there is no intention that the appended claims be limited by the title, technical field, background, or abstract.

### DETAILED DESCRIPTION OF THE INVENTION

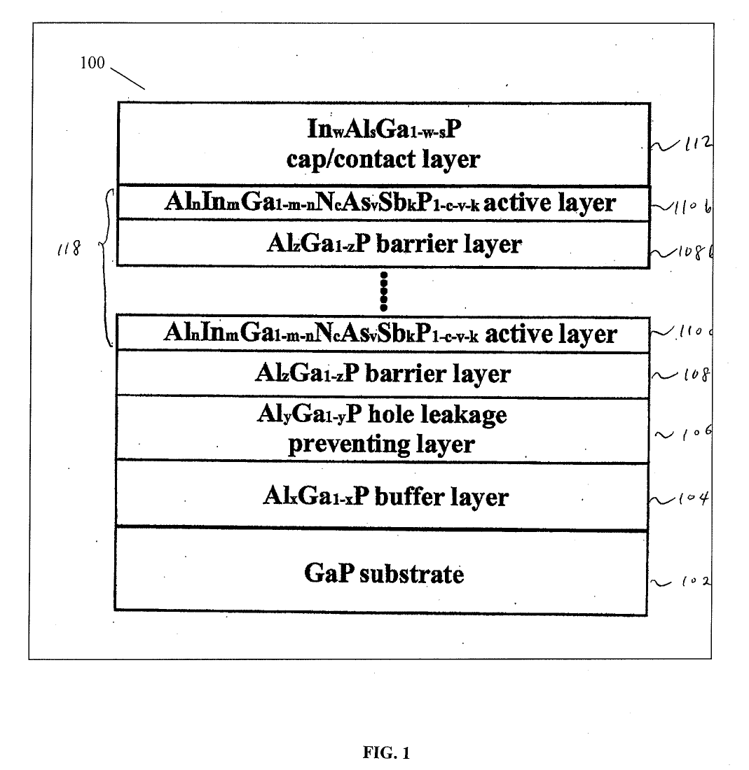

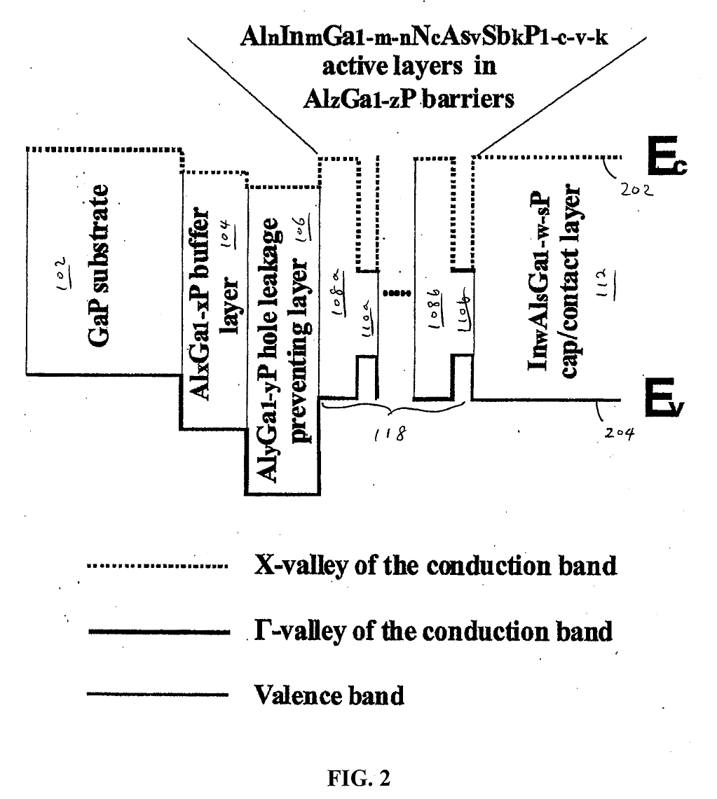

FIG. 1 shows an exemplary LED structure 100 of the present invention. The LED structure comprises a substrate 102, a buffer layer 104, a hole-leakage-prevention layer 106, a plurality of barrier layers 108, a plurality of active layers 110 and a cap/contact layer 112. FIG. 2 shows a schematic of one of the possible band diagrams for the LED structure 100 shown in FIG. 1. E_{c} is the conduction band minimum, while Eᵥ is the valence band maximum.

Substrate 102 may comprise GaP or silicon, however this is not a limitation of the present invention and in other embodiments other substrates may be used, such as sapphire, AlN, plastic, quartz, glass, metal, etc.

Buffer layer 104 may comprise AlₓGa₁₋ₓP where 0≦x≦1 and be formed over a substrate 102. Buffer layer 104 may be useful to obtain a smooth surface on substrate 102 for subsequent growth of the layers comprising LED structure 100. In some embodiments buffer layer 104 may be undoped or doped n-type or p-type. In some embodiments buffer layer 104 may be doped with the same doping type as substrate 102. For example, in one embodiment substrate 102 and buffer layer 104 may be n-type.

Hole-leakage-prevention layer 106 may comprise Al_{w}Ga_{1-w}P where 0≦w≦1 and may be formed over buffer layer 104 or over substrate 102. Hole-leakage-prevention layer 106 may help to confine the holes in active region 118 of LED structure 100 and to prevent the leakage of holes from active region 118. Note that hole-leakage prevention layer 106 confines only holes, since it forms a type-II (“staircase”) heterojunction with barrier layer 108, which may itself comprise Al_{z}Ga_{1-z}P where 0≦z≦1 (See FIG. 2). A large valence band offset may be achieved when hole-leakage-prevention layer 106 comprises AlP and barrier layer 108 comprises GaP. The valence band offset in this case is about 0.5 eV, which may be large enough to provide strong confinement for holes in active region 118. In some embodiments, hole-leakage prevention layer 106 may be undoped or doped n-type or p-type.

Active region 118 may comprise a plurality of Al_{z}Ga_{1-z}P where 0≦z≦1 barrier layers 108 interleaved with a plurality of AlₙInₘGa₁₋ₘ₋ₙN_{c}AsᵥSbₖP_{1-c-v-k} where 0.001<c<0.1 and 0≦n,m,v,k≦1 active layers 110. Barrier layers 108 may have a larger bandgap than active layers 110, as shown in FIG. 2. FIG. 2 also shows the relatively large conduction band and valence band offsets between barrier layers 108 and active layers 110. The conduction band offset for the present invention may be about three times larger than that for conventional AlInGaP materials, leading to improved carrier confinement. The active layers 110a, 110b, etc. comprise a direct-bandgap semiconductor from which the light is emitted. A recombination process of carriers (i.e. electrons and holes) occurs in active layers 110 that are interleaved with barrier layers 108. A plurality of active layers 110 may be utilized to maximize light-generation from the carriers injected into LED structure 100. In some embodiments, active layers 110 may be undoped or doped n-type or p-type. In some embodiments, barrier layers 108 may be undoped or doped n-type or p-type.

Cap/contact layer 112, may comprise AlₙInₘGa₁₋ₘ₋ₙP where 0≦n,m≦1 and may be formed over active region 1 18. Cap/contact layer 112 may be used to provide a reduced contact resistance to an external electrode contact for LED 100. Cap/contact layer 112 may also provide current spreading so that current injected into LED structure 100 from a metal contact (not shown in FIGS. 1 or 2) formed over cap/contact layer 112 may be uniformly distributed over all or substantially all of the area of active region 118. Decreasing the bandgap in cap/contact layer 112 may help reduce the Schottky barrier between cap/contact layer 112 and a metal electrode or a contact pad (not shown FIGS. 1 or 2) formed over cap/contact layer 112, and thus reduce the contact resistance. The bandgap in cap/contact layer 112 may be decreased by adding or increasing the indium concentration in this layer. In some embodiments, cap/contact layer 112 may be undoped or doped n-type or p-type. In some embodiments, cap/contact layer 112 may be doped with an opposite doping type as compared to substrate 102. For example, in one embodiment, if substrate 102 is n-type, cap/contact layer 112 may be p-type.

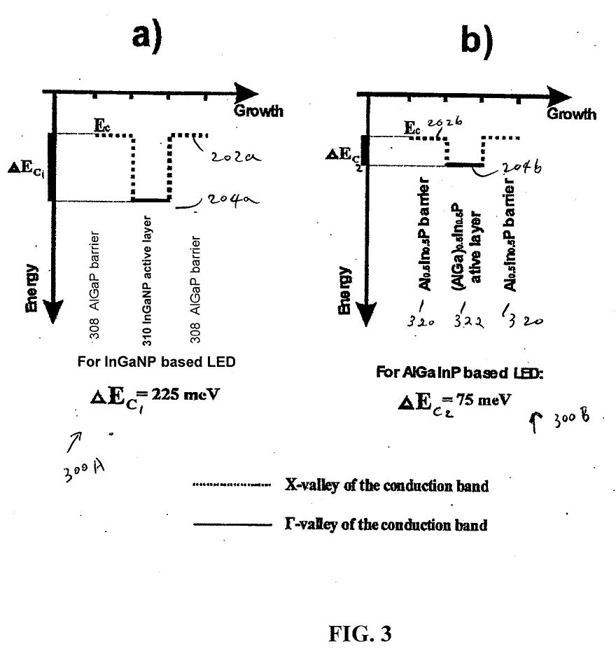

FIGS. 3A-3B show the conduction band diagram for a GaP/InGaNP/GaP heterostructure in accordance with an embodiment of the invention and a conventional Al_{0.5}In_{0.5}P/(AlGa)_{0.5}In_{0.5}P/Al_{0.5}In_{0.5}P heterostructure, respectively. Because both GaP and Al_{0.5}In_{0.5} P are indirect bandgap materials, the conduction band minimum E_{c} of the indirect band materials may be at X valley 202a and 202b with a finite electron momentum, as shown by horizontal dashed lines. On the other hand, compositions of InGaNP and (AlGa)_{0.5}In_{0.5}P may be chosen to have direct bandgaps, so that the conduction band minimum E_{c} of the direct bandgap material may be at a Γ-valley 204a and 204b with a zero electron momentum, as shown by horizontal solid lines. Generally, electrons may reside at the conduction band minimum E_{c}, while holes may reside at the valence band maximum Eᵥ. Hence, in heterostructures such as those shown in FIGS. 3A-3B, electrons may reside in the lower energy InGaNP or (AlGa)_{0.5}In_{0.5}P active layers, and may be confined by the higher energy GaP or Al_{0.5}In_{0.5}P barriers, respectively. The energy difference between X-valley 202 and Γ-valley 404 is called the band offset ΔE_{c}.

At elevated temperature, electrons confined in a shallow energy well may acquire enough thermal energy to overcome the energy barrier or band offset ΔE_{c} and leave the active layer. If this occurs, these electrons may recombine in a non-radiative fashion outside of the active layer. The result of this is reduced brightness and reduced efficiency. Therefore, a larger energy barrier ΔE_{c} may result in better electron confinement in the active layer and thus higher brightness and increased efficiency at elevated temperatures.

As the LED drive current increases, the population of carriers in the active layer increases and carriers nearer to the top of the well face a smaller energy barrier than carriers nearer to the bottom of the well. At high enough drive current, carriers nearer to the top of the well may acquire enough energy to overcome the band offset ΔE_{c} and leave the active layer. As discussed above, this may result in reduced brightness and reduced efficiency. Therefore, a larger energy barrier ΔE_{c}may result in better electron confinement in the active layer and thus higher brightness and increased efficiency at high drive currents.

Referring to FIGS. 3A and 3B again, the conduction band offset ΔE_{c1} between Al_{z}Ga_{1-z}P barrier layer 308 and InGaNP-based active layer 310 for the LED structure 300A is about 225 meV, which is about three times the conduction band offset ΔE_{c2} between AlInP barrier layer 320 and AlInGaP active layer 322 (i.e. about 75 meV) for AlInGaP-based conventional LED 300B. In some embodiments, the conduction band offset ΔE_{c}₁ may be large enough to provide sufficient electron confinement in InGaNP-based active layer 310, so that no extra electron confinement layer is needed outside the active region of LED structure 300A, as is required in the case for conventional AlInGaP-based LED 300B. The valence band offset ΔEᵥ of the LED structure 100 described herein may be greater than 150 meV, whereas that of a conventional AlInGaP-based LED structure is about 150 meV. While the example shown in FIG. 3A refers to an InGaNP-based active layer, this is not a limitation of the present invention and in other embodiments, the active layer may comprise AlₙInₘGa₁₋ₘ₋ₙN_{c}AsᵥSbₖP_{1-c-v-k} where 0≦n, m, v, k≦1 and 0.001<c<0.1.

In some embodiments an optional Al_{w}Ga_{1-w}P where 0≦w≦1 hole-leakage prevention layer 106 may be formed over substrate 102 or buffer layer 104 prior to the formation of active region 118. The bandgap of hole-leakage prevention layer 106 may be greater than that of buffer layer 104 or substrate 102. For example buffer layer 104 may comprise AlₓGa₁₋ₓP and hole-leakage prevention layer 106 may comprise Al_{w}Ga_{1-w}P and w>x. In another example, buffer layer 104 may comprise GaP and hole-leakage prevention layer 106 may comprise AlₓGa₁₋ₓP where 0<x≦1. Hole-leakage prevention layer 106 may be undoped or doped n-type or p-type.

In some embodiments of the invention, an optional Al_{y}Ga_{1-y}P where 0≦y≦1 current spreading/blocking layer may be formed over, within or under cap/contact layer 112. The bandgap of the current spreading/blocking layer may be greater than that of cap/contact layer 112. The current spreading/blocking layer may be undoped or doped n-type or p-type.

In some embodiments of the invention, an optional Al_{y}Ga_{1-y}P where 0≦y≦1 current spreading/blocking layer may be formed over, within or under buffer layer 104. The bandgap of the current spreading/blocking layer may be greater than that of buffer layer 104. The current spreading/blocking layer may be undoped or doped n-type or p-type.

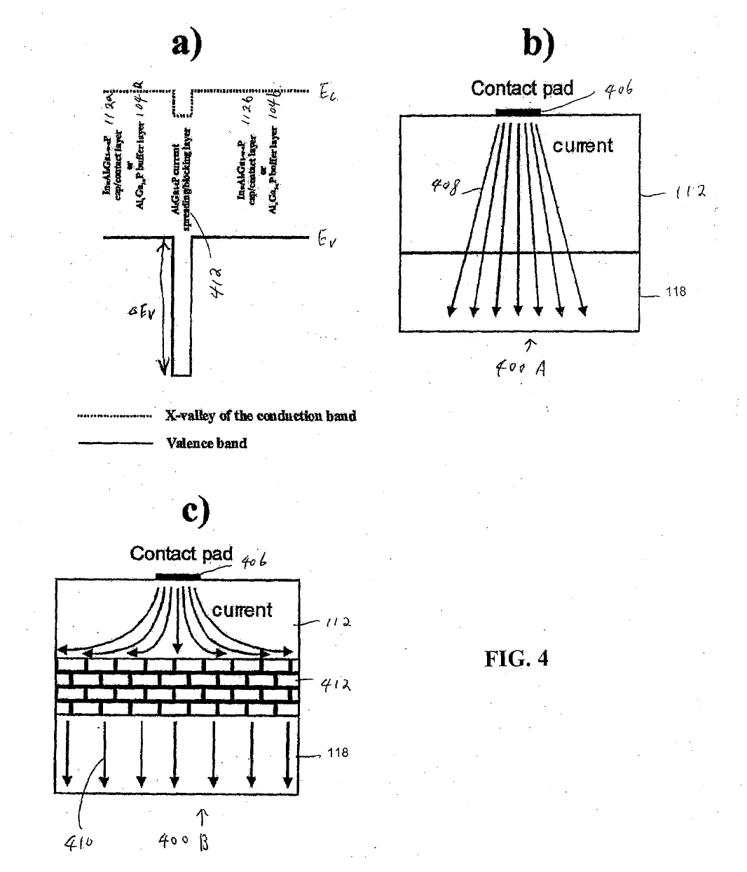

FIG. 4A shows an Al_{y}Ga_{1-y}P where 0≦y≦1 current spreading/blocking layer 412 between two AlₙInₘGa₁₋ₘ₋ₙP where 0≦n,m≦1 cap/contact layers 112a and 112b or between two Al_{y}Ga_{1-y}P where 0≦y≦1 buffer layers 104a and 104b. Current spreading/blocking layer 412 may be used to enhance the electrical and optical properties of LED structure 100 (FIG. 1). Current spreading/blocking layer 412 may have a valence band offset ΔEᵥ with respect to AlₙInₘGa₁₋ₘ₋ₙP where 0≦n,m≦1 cap/contact layer 112 or with respect to Al_{y}Ga_{1-y}P where 0≦y≦1 buffer layer 104. In some embodiments, the valence band offset ΔEᵥ may be greater than 0.3 eV. In other embodiments, the valence band offset ΔEᵥ may be as large as 0.5 eV.

FIG. 4B shows the current in a structure 400A without a current spreading/blocking layer. In this case, the current flows from contact 406 into active region 118 in a “shower-head-like” manner from cap/contact layer 112, which results in non-uniform current injection as shown by lines 408 in active region 118.

FIG. 4C shows the current in a structure incorporating current spreading/blocking layer 412 of the invention between cap/contact layer 112 and active region 118. As shown in FIG. 4C, current spreading/blocking layer 412 may allow current flow from contact 406 to be spread out in cap/contact layer 112 and may provide uniform current injection in the active region 118 as shown by lines 410. In this way, greater uniformity of current injection may be achieved in the active region 118. Current spreading/blocking layer 412 may be sufficiently thick to provide improved current spreading, but may be thin enough to provide a satisfactory current-voltage diode characteristic. Although the example above shows the current spreading/blocking layer formed between the cap/contact layer and the active region, this is not a limitation of the present invention and in other embodiments the current spreading/blocking layer may be formed over, within, or under the cap/contact layer or over, within, or under the buffer layer, or both.

Contact pad 406 shown in FIG. 4C may be made as small as possible so that contact pad 406 does not cover the surface of LED 100 and thus reduces the light emission from LED 100. However, decreasing the size of contact pad 406 may lead to carrier injection into a smaller area of active region 118 of LED 400, and thus may decrease the light emission. Therefore, an intermediate size of contact pad 406 may help maximize light emission from LED 100.

In some embodiments of the present invention, all of the layers of the LED except the active layer may have indirect-bandgaps and thus are transparent to the light emitted from the active layer. In these embodiments, there is relatively very little absorption of the emitted light in the remainder of the structure, resulting in a relatively high efficiency.

In a further embodiment of the invention, a variation of LED structure 100 of FIG. 1 provides the use of n-type and p-type delta doping layers deposited on interfaces between specified layers, or inside the specified layers, such as the substrate, buffer layer or cap layer. These doping layers enhance the current-voltage characteristic of the diode. As used herein, delta doping (i.e., “atomic plane doping”) refers to depositing impurity atoms (donors or acceptors) on a growth-interrupted surface or in a very narrow region, for example less than 10 Å. Delta doping may provide locally high doping concentrations. Use of delta doped layers may reduce the potential barrier for carriers at the interface of heterojunctions, and thus may enhance current-voltage characteristics.

All of the above described structures, as well as separate layers or parts of the layers of the specified structures, may be formed using a superlattice or a digital alloy technique rather than being formed in a way that may produce a random alloy. In a random alloy AₓB₁₋ₓC, A and B atoms may be randomly. distributed throughout one sub-lattice, while C atoms occupy a second sub-lattice.

In a superlattice or digital alloy such as alternating thin layers of AC/BC/AC/BC, the average elemental composition (i.e., ratios of A to B to C) may be made the same as that in a random alloy by adjusting the relative thickness of layers AC and BC. The layers are thin enough that carriers may move throughout the layers as in the random alloy so that some macroscopic properties of the digital alloy may be similar to those of the random alloy. For example, a plurality of AlP/GaP thin layers (digital alloy), rather than a thick AlGaP layer (random alloy), may be preferred because the digital alloy may end in a GaP layer to prevent a layer comprising aluminum, which may be reactive, from contact with air.

In another embodiment of the present invention, the optical and/or electrical properties of the LED may be enhanced by the use of annealing during growth, after the growth is complete, or both. Annealing may comprise heating portions or all of the structure to a temperature higher than the maximum temperature used for formation of the structure. In another embodiment, portions of the structure may be annealed at temperatures higher than the maximum temperature used to form that particular part of the structure.

Several types of recombination processes may occur in the active region of an LED, such as radiative recombination resulting in photon emission and non-radiative recombination processes (e.g., via a deep level or via an Auger process). In non-radiative recombination processes, the energy released may convert into phonons or heat.

In general, non-radiative recombination events may be desired to be minimized or eliminated. One of the more common causes of non-radiative recombination events is defects, such as vacancies, dislocations impurities (for example foreign or undesired atoms) as well as complexes and combinations of various types of defects. Such defects have different energy levels than those in the undefected material e.g. those that result from the desired (or substitutional) atoms. The energy levels associated with defects may act as deep levels or non-radiative recombination centers, resulting in reduced light emission and decreased efficiency.

One element of the present invention is the incorporation of a relatively small amount of nitrogen into the one or more active layers of the LED. Incorporation of nitrogen may produce a number of point defects in and around the one or more active layers because of the smaller size of the nitrogen atom relative to the other atoms in the one or more active layers. These point defects may form non-radiative recombination centers which may degrade the optical and electrical properties of the LED.

Accordingly, a specific embodiment of the present invention comprises enhancing the optical properties of the LED structure by annealing the LED structure during and/or after growth. The annealing of the LED structure comprises heating the substrate to an elevated temperature that is higher than the maximum temperature used for growth of the LED structure. Annealing may help reduce the number of point defects in the LED structure, especially in and around the nitrogen-containing active region, thus enhancing the light emitting efficiency of the LED structure.

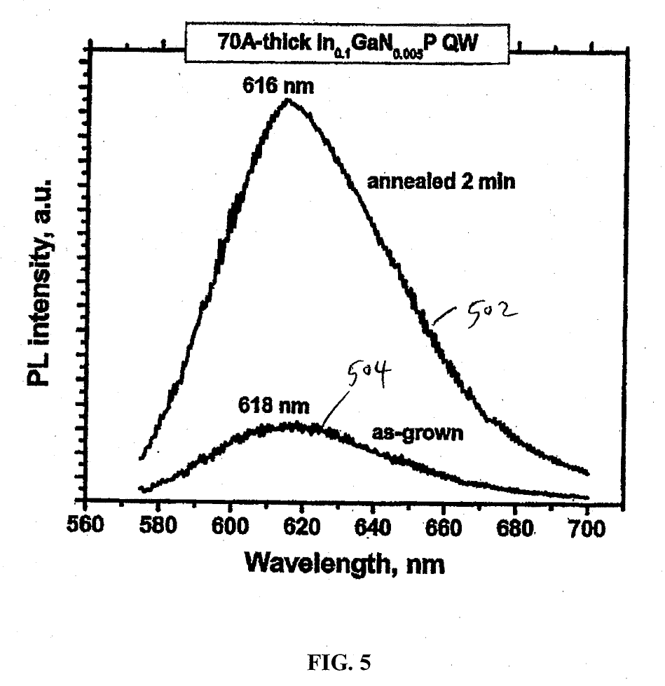

FIG. 5 shows the results of photoluminescence experiments on samples with and without annealing. In FIG. 5, spectrum 502 shows the photoluminescence intensity as a function of wavelength for a sample with a 7 nm thick InGaNP active layer sandwiched between GaP barriers which was annealed in the growth chamber after the growth of the LED structure under a phosphorus environment. The annealing was performed at 700° C. for 2 minutes. Compare curve 504 in FIG. 5 shows the photoluminescence intensity as a function of wavelength for an identical sample that had no annealing. It is clear that annealing may increase the photoluminescence intensity; in this case the photoluminescence intensity has increased by a factor of about 5.

All LEDs exhibit some shift in emission wavelength (or color) with changes in drive current or temperature. In most cases the change is a red shift; that is, the emission wavelength increases with increasing temperature and/or drive current. The reason for the red shift is that higher drive current increases the ambient junction temperature and thus decreases the bandgap. The reduced bandgap leads to a peak shift of the emitted wavelength toward the red color region. Therefore, when an LED is operated at higher temperature, either because of increased drive current or in environments where the temperature is higher, the color of the emitted light is changed compared to an operation at ambient temperature.

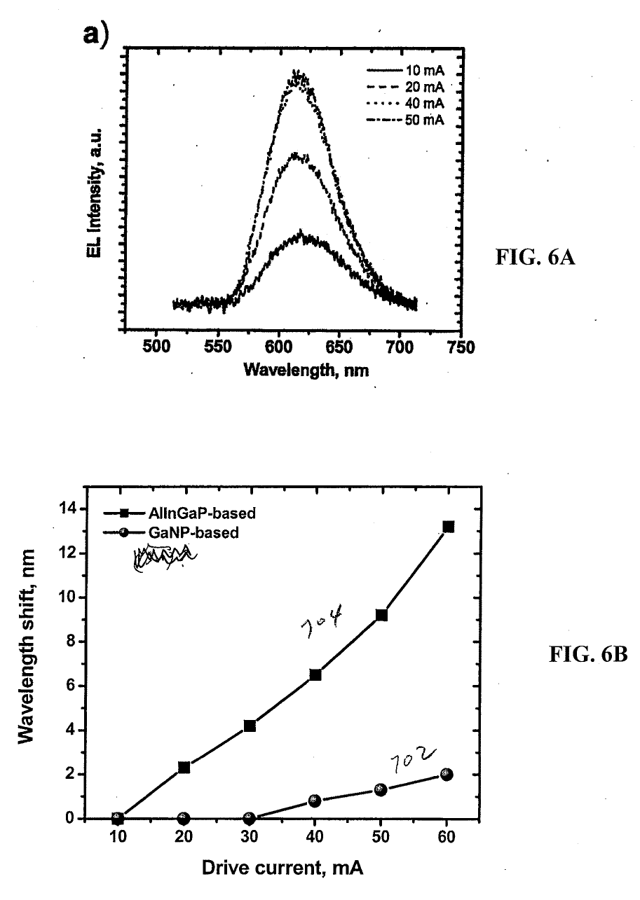

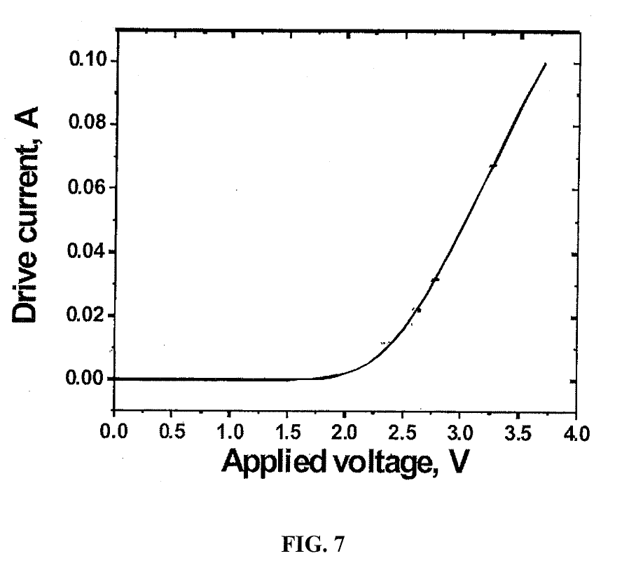

FIG. 6A shows electroluminescence spectra of a fabricated LED of embodiments of the present invention at various drive currents. The spectra shown in FIG. 6A demonstrate that little to no shift in emission peak wavelength is seen at drive currents of at least up to 50 mA. The small shift in peak wavelength at increasing drive currents is an intrinsic property of the LEDs of embodiments of the present invention. As such, LEDs of embodiments of the present invention should demonstrate a relatively smaller wavelength shift with drive current compared to AlInGaP-based LEDs. FIG. 6B shows the red shift of a commercial AlInGaP-based LED (curve 704) as compared to the red shift (curve 702) of a fabricated LED of an embodiment of the present invention. A commercial AlInGaP-based bare LED chip shows about 13 nm of red shift, when the drive current is increased from 10 mA to 60 mA, as compared to about 2 nm of red shift for a fabricated LED of an embodiment of the present invention across the same range of drive currents. Thus the LED of an embodiment of the present invention provides a color shift with respect to drive current that is about 3 to about 6 times less than that of the conventional AlInGaP LEDs. FIG. 7 shows the current-voltage characteristics of a fabricated LED of the present invention. Note that the drive current has a linear dependence upon the drive voltage from between 15 mA to 20 mA to at least 100 mA.

One aspect of the LED of the present invention is that the LED structure may be grown on a transparent GaP substrate in a one-step epitaxial process, which may be defect-free and simpler than the conventional process for the AlInGaP LED. The conventional process requires growth of the LED structure on an absorbing GaAs substrate. If the absorbing GaAs substrate is left in place, a great deal of the generated light may be absorbed by the GaAs substrate, resulting in greatly reduced efficiency and brightness. Absorption in the GaAs substrate may be reduced or eliminated by a number of approaches, each of which add to the cost and reduce the yield of the LEDs. For example the light-absorbing GaAs substrate may be removed by etching and replaced by a transparent GaP substrate or a reflective submount. This approach requires additional steps, including removal of the GaAs substrate and wafer bonding of a GaP substrate to the LED structure, or mounting of the LED structure to a submount, in addition to the extra cost of the GaAs substrate. This multiple-step process increases the complication of manufacturing and cost. In another approach a distributed Bragg reflector (DBR) may be formed in between the absorbing substrate and the AlInGaP LED structure. As discussed above, this adds additional cost and may reduce the yield. Furthermore, DBRs in general have reduced reflectivity for light incident at shallow angles, and thus the efficiency increase from this approach is relatively smaller than that achieved by the wafer bonding approach. The LED of the present invention eliminates the need for these extra costs and steps by growth of the LED structure directly on the GaP transparent substrate.

The above features of the LED of the present invention make many industrial applications possible with enhanced performance at reduced cost, including full-color displays, signaling, traffic lights, automotive lights, outdoor displays, and back lighting of cell phones among others. The LED industry may replace incandescent lamps and fluorescent tubes with white LEDs.

Thus, having described several embodiments, it will be recognized by those of skill in the art that various modifications, alternative constructions, and equivalents may be used without departing from the spirit of the invention. Accordingly, the above description should not be taken as limiting the scope of the invention, which is defined in the following claims.

What is claimed:

1. A light-emitting diode comprising:
a substrate;
a buffer layer disposed over the substrate;
a barrier layer disposed over the substrate;
an active layer comprising a gallium phosphide based, direct bandgap AlₙInₘGa₁₋ₘ₋ₙN_{c}AsᵥSbₖP_{1-c-v-k} where 0≦n, m, v, k≦1 and c>0.004 disposed over the barrier layer; and
a cap/contact layer disposed over the active layer.

2. The light-emitting diode of claim 1 wherein the active layer comprises 0.004<c<0.1 and the active layer is selected from the group consisting of nitrogen containing gallium phosphide, nitrogen and arsenic containing gallium phosphide, nitrogen and indium containing gallium phosphide, nitrogen, arsenic, and antimony containing gallium phosphide, nitrogen, arsenic, and indium containing gallium phosphide, and nitrogen, arsenic, antimony, and indium containing gallium phosphide.

3. The light-emitting diode of claim 1 wherein the substrate is a GaP substrate.

4. The light-emitting diode of claim 1 wherein the buffer layer comprises AlₓGa₁₋ₓP where 0≦x≦1.

5. The light-emitting diode of claim 4 wherein the barrier layer comprises Al_{y}Ga_{1-y}P where 0≦y≦1, and x≦y.

6. The light-emitting diode of claim 1 wherein the cap/contact layer comprises AlₙInₘGa₁₋ₘ₋ₙP where 0≦n,m≦1.

7. The light-emitting diode of claim 1 wherein the barrier layer and active layer comprise a plurality of barrier layers and a plurality of active layers and the plurality of active layers are interleaved with the plurality of barrier layers.

8. The light-emitting diode of claim 8 wherein the composition of each barrier layer in the plurality of barrier layers is substantially the same.

9. The light-emitting diode of claim 8 wherein the composition of each active layer in the plurality of active layers is substantially the same.

10. The light-emitting diode of claim 1 further comprising at least one Al_{w}Ga_{1-w}P where 0≦w≦1 hole-leakage prevention layer disposed over the substrate, the hole-leakage prevention layer having a bandgap larger than that of a underlying material.

11. The light-emitting diode of claim 1 wherein the substrate comprises a doped n-type substrate or a doped p-type substrate;
the buffer layer comprises a doped buffer layer of the same doping type as the substrate; and
the cap/contact layer comprises a doped cap/contact layer opposite in type to that of the substrate.

12. The light-emitting diode of claim 1 further comprising at least one Al_{w}Ga_{1-w}P where 0≦w≦1 current spreading/blocking layer disposed over, within or under the buffer layer, the current spreading/blocking layer having a bandgap larger than that of the buffer layer.

13. The light-emitting diode of claim 1 further comprising at least one Al_{w}Ga_{1-w}P where 0≦w≦1 current spreading/blocking layer disposed over, within or under the cap/contact layer, the current spreading/blocking layer having a bandgap larger than that of the cap/contact layer.

14. The light-emitting diode of claim 1 wherein a wavelength emitted from the light-emitting device ranges from about 540 nm to about 700 nm.

15. The light-emitting diode of claim 1 wherein at least one delta doped layer is disposed over the substrate.

16. The light-emitting diode of claim 1 wherein a portion or all of the layers or a portion of some or all layers are formed using a superlattice or digital alloy technique.

17. A method of forming a light emitting device comprising:
introducing a substrate in a processing chamber;
forming a buffer layer disposed over the substrate;
forming a barrier layer disposed over the substrate;
forming an active layer comprising gallium phosphide based, direct bandgap AlₙInₘGa₁₋ₘ₋ₙN_{c}AsᵥSbₖP_{1-c-v-k} where 0≦n, m, v, k≦1 and c>0.004 layer disposed over the barrier layer; and
forming a cap/contact layer disposed over the active layer;
wherein the device is annealed between the formation of any two layers or after all layers have been formed with an annealing temperature higher than the highest formation temperature.

18. The method of claim 17 wherein the active layer comprises 0.004<c<0.1 and the active layer is selected from the group consisting of nitrogen containing gallium phosphide, nitrogen and arsenic containing gallium phosphide, nitrogen and indium containing gallium phosphide, nitrogen, arsenic, and antimony containing gallium phosphide, nitrogen, arsenic, and indium containing gallium phosphide, and nitrogen, arsenic, antimony, and indium containing gallium phosphide.

19. A light-emitting diode comprising:
an n-type GaP substrate;
an n-type buffer layer comprising AlₙGa₁₋ₙP where 0≦n≦1 disposed over the substrate;
a plurality of barrier layers comprising AlₙGa₁₋ₙP where 0≦n≦1 interleaved with a plurality of gallium phosphide based, direct band gap active layers comprising AlₙInₘGa₁₋ₘ₋ₙN_{c}AsᵥSbₖP_{1-c-v-k} where 0≦n, m, v, k≦1 and c>0.004 disposed over the buffer layer; and
a p-type cap/contact layer comprising AlₙInₘGa₁₋ₘ₋ₙP where 0≦n,m≦1 disposed over the last active layer or barrier layer.

20. The light emitting diode of claim 19 wherein the plurality of active layers comprising AlₙInₘGa₁₋ₘ₋ₙN_{c}AsᵥSbₖP_{1-c-v-k} where 0.001<c<0.1 and 0≦n,m,v,k≦1 comprise GaN_{c}AsᵥP_{1-c-v} where 0.001<c<0.1 and 0≦v≦1.

21. The light emitting diode of claim 19 wherein the plurality of active layers comprising AlₙInₘGa₁₋ₘ₋ₙN_{c}AsᵥSbₖP_{1-c-v-k} k where 0.001<c<0.1 and 0≦n,m,v,k≦1 comprise InₘGa₁₋ₘN_{c}P_{1-c} where 0.001<c<0.1 and 0≦m≦1.

22. The light emitting diode of claim 19 wherein the plurality of active layers comprising AlₙInₘGa₁₋ₘ₋ₙN_{c}AsᵥSbₖP_{1-c-v-k} where 0.001<c<0.1 and 0≦n,m,v,k≦1 comprise GaN_{c}P_{1-c} where 0.001<c<0.1.

23. The light emitting diode of claim 19 wherein the n-type AlₙGa₁₋ₙP where 0≦n≦1 buffer layer comprises n-type GaP, the AlₙGa₁₋ₘ₋ₙP where 0≦n≦1 barrier layer comprises GaP and the p-type AlₙInₘGa₁₋ₘ₋ₙP where 0≦n,m≦1 cap/contact layer comprises p-type GaP.

24. The light-emitting diode of claim 19 wherein the active layer comprises 0.004<c<0.1 and the active layer is selected from the group consisting of nitrogen containing gallium phosphide, nitrogen and arsenic containing gallium phosphide, nitrogen and indium containing gallium phosphide, nitrogen, arsenic, and antimony containing gallium phosphide, nitrogen, arsenic, and indium containing gallium phosphide, and nitrogen, arsenic, antimony, and indium containing gallium phosphide.

25. A method of forming a light emitting diode comprising:
introducing a substrate in a processing chamber;
forming a buffer layer disposed over the substrate;
forming a barrier layer disposed over the substrate;
forming an active layer comprising gallium phosphide based, direct bandgap AlₙInₘGa₁₋ₘ₋ₙN_{c}AsᵥSbₖP_{1-c-v-k} where 0≦n, m, v, k≦1 and c>0.004 layer disposed over the barrier layer; and
forming a cap/contact layer disposed over the active layer.

26. The method of claim 25 wherein the active layer comprises 0.004<c<0.1 and the active layer is selected from the group consisting of nitrogen containing gallium phosphide, nitrogen and arsenic containing gallium phosphide, nitrogen and indium containing gallium phosphide, nitrogen, arsenic, and antimony containing gallium phosphide, nitrogen, arsenic, and indium containing gallium phosphide, and nitrogen, arsenic, antimony, and indium containing gallium phosphide.
